(19) United States
(12) Patent Application Publication
(10) Pub. No.: US 2015/0162435 A1
(43) Pub. Date: Jun. 11, 2015

(54) ASYMMETRIC CHANNEL GROWTH OF A CLADDING LAYER OVER FINS OF A FIELD EFFECT TRANSISTOR (FINFET) DEVICE

(71) Applicant: GLOBALFOUNDRIES INC., Grand Cayman (KY)

(72) Inventors: Bhagawan Sahu, Watervliet, NY (US); Zoran Krivokapic, Santa Clara, CA (US)

(21) Appl. No.: 14/100,196

(22) Filed: Dec. 9, 2013

(51) Int. Cl. H01L 29/78; H01L 29/66; H01L 21/02; H01L 29/06

(52) U.S. Cl. CPC H01L 29/785; H01L 29/0657; H01L 29/66795; H01L 21/02123

(57) ABSTRACT

Approaches for providing asymmetrical channel growth of a cladding layer over fins of a fin field effect transistor (FinFET) device are disclosed. Specifically, in one approach, a FinFET device comprises a set of fins formed from a substrate, a shallow trench isolation layer formed adjacent each of the set of fins, and a cladding layer (e.g., silicon germanium) formed over each of the set of fins, wherein a thickness of the cladding layer atop each of the set of fins is greater than a thickness of the cladding layer along each sidewall of the set of fins. In one embodiment, the thickness of the cladding layer atop the set of fins is approximately two times (2×) greater than the thickness of the cladding layer along each sidewall of the set of fins.

### BACKGROUND

1. Technical Field

This invention relates generally to the field of semiconductors, and more particularly, to forming a cladding over a set of fins of a FinFET device.

2. Related Art

A typical integrated circuit (IC) chip includes a stack of several levels or sequentially formed layers of shapes. Each layer is stacked or overlaid on a prior layer and patterned to form the shapes that define devices (e.g., field effect transistors (FETs)) and connect the devices into circuits. In a typical state of the art complementary insulated gate FET process, such as what is normally referred to as CMOS, layers are formed on a wafer to form the devices on a surface of the wafer. Further, the surface may be the surface of a silicon layer on a silicon on insulator (SOI) wafer. A simple FET is formed by the intersection of two shapes, a gate layer rectangle on a silicon island formed from the silicon surface layer. Each of these layers of shapes, also known as mask levels or layers, may be created or printed optically through well known photolithographic masking, developing and level definition, e.g., etching, implanting, deposition, etc.

The FinFET is a transistor design that attempts to overcome the issues of short-channel effect encountered by deep submicron transistors, such as drain-induced barrier lowering (DIBL). Such effects make it harder for the voltage on a gate electrode to deplete the channel underneath and stop the flow of carriers through the channel—in other words, to turn the transistor off. By raising the channel above the surface of the wafer instead of creating the channel just below the surface, it is possible to wrap the gate around all but one of its sides, providing much greater electrostatic control over the carriers within it.

Conventional FinFET formation utilizes hard-mask and etching processes to etch away the surrounding area, creating the fin. The trenches on each side of the fin are then filled with oxide, and excess oxide is removed with chemical mechanical planarization (CMP) and/or oxide etching. The fins are sometimes clad with epitaxially grown silicon/germanium (SiGe) or germanium (Ge) to enhance nFET and pFET performance, respectively. However, in this conventional approach, hole charge spill out from the SiGe cladding layer on each fin leads to decreased device performance.

### SUMMARY

In general, approaches for providing asymmetrical channel growth of a cladding layer over fins of a fin field effect transistor (FinFET) device are disclosed. Specifically, in one approach, a FinFET device comprises a set of fins formed from a substrate, a shallow trench isolation layer formed adjacent each of the set of fins, and a cladding layer (e.g., silicon germanium) formed over each of the set of fins, wherein a thickness of the cladding layer atop each of the set of fins is greater than a thickness of the cladding layer along each sidewall of the set of fins. In one embodiment, the thickness of the cladding layer atop the set of fins is approximately two times (2×) greater than the thickness of the cladding layer along each sidewall of the set of fins. As such, a hole charge spill out resulting from the cladding layer atop the set of fins is beneficially confined within the channel.

One aspect of the present invention includes a fin field effect transistor (FinFET) device, comprising: a set of fins formed from a substrate; a shallow trench isolation layer adjacent each of the set of fins; and a cladding layer formed over each of the set of fins, wherein a thickness of the cladding layer atop each of the set of fins is greater than a thickness of the cladding layer along each sidewall of the set of fins.

Another aspect of the present invention includes a method for forming a fin field effect transistor (FinFET) device, the method comprising: forming a set of fins from a substrate; forming a shallow trench isolation layer adjacent each of the set of fins; and forming a cladding layer formed over each of the set of fins, wherein a thickness of the cladding layer atop each of the set of fins is greater than a thickness of the cladding layer along each sidewall of the set of fins.

Yet another aspect of the present invention includes a method for providing asymmetrical channel growth of a cladding layer over fins of a fin field effect transistor (FinFET) device, the method comprising: forming a set of fins from a substrate; forming a shallow trench isolation layer adjacent each of the set of fins; and forming a cladding layer formed over each of the set of fins, wherein a thickness of the cladding layer atop each of the set of fins is greater than a thickness of the cladding layer along each sidewall of the set of fins.

### BRIEF DESCRIPTION OF THE DRAWINGS

These and other features of this invention will be more readily understood from the following detailed description of the various aspects of the invention taken in conjunction with the accompanying drawings in which:

FIG. 1(a) shows a cross-sectional view of a substrate and cladding layer of a FinFET device according to illustrative embodiments;

FIG. 1(b) shows a cross-sectional view of the substrate and cladding layer of the FinFET device following formation of a fin according to illustrative embodiments;

FIG. 1(c) shows a cross-sectional view of the FinFET device following formation of a shallow trench isolation layer according to illustrative embodiments;

FIG. 1(d) shows a cross-sectional view of the FinFET device following formation of the cladding layer along each sidewall of the fin according to illustrative embodiments;

FIG. 2(a) shows a cross-sectional view of a FinFET device following formation of a fin therein according to illustrative embodiments;

FIG. 2(b) shows a cross-sectional view of the FinFET device following formation of a shallow trench isolation layer according to illustrative embodiments;

FIG. 2(c) shows a cross-sectional view of the FinFET device following formation of the cladding layer over the fin according to illustrative embodiments; and

FIG. 3 shows a process flow for providing asymmetrical channel growth of the cladding over fins of the FinFET device according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Furthermore, for clarity, some reference numbers may be omitted in certain drawings.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art.

The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

As used herein, “depositing” may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

As mentioned above, approaches herein provide asymmetrical channel growth of a cladding layer over fins of a FinFET device. Specifically, in one approach, a FinFET device comprises a set of fins formed from a substrate, a shallow trench isolation layer formed adjacent each of the set of fins, and a cladding layer (e.g., silicon germanium) formed over each of the set of fins, wherein a thickness of the cladding layer atop each of the set of fins is greater than a thickness of the cladding layer along each sidewall of the set of fins. In one embodiment, the thickness of the cladding layer atop the set of fins is approximately two times (2×) greater than the thickness of the cladding layer along each sidewall of the set of fins. Controlling the SiGe cladding layer thickness can mitigate or suppress the charge spillage into the fin, and results in an asymmetric cladding channel FinFET.

It will be appreciated that portions of the finFET device structure are formed using well-known techniques and process steps (e.g., techniques and steps related to doping, photolithography and patterning, etching, material growth, material deposition, surface planarization, and the like) that will not be described in detail here. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well-known process details.

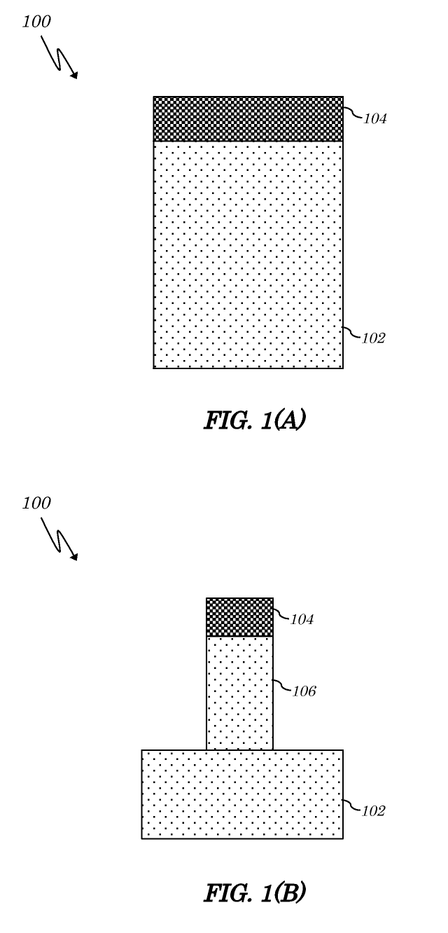

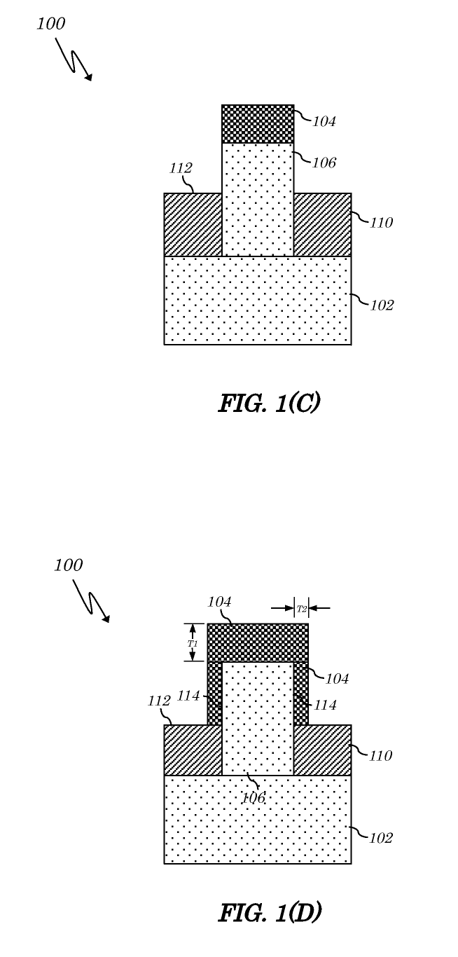

With reference now to the figures, FIG. 1(a) shows a cross-sectional view of a device 100 (e.g., a FinFET device) including a substrate 102, and a cladding layer 104 formed atop substrate 102. The term “substrate” as used herein is intended to include a semiconductor substrate, a semiconductor epitaxial layer deposited or otherwise formed on a semiconductor substrate and/or any other type of semiconductor body, and all such structures are contemplated as falling within the scope of the present invention. For example, the semiconductor substrate may comprise a semiconductor wafer (e.g., silicon, SiGe, or an SOI wafer) or one or more die on a wafer, and any epitaxial layers or other type semiconductor layers formed thereover or associated therewith. A portion or the entire semiconductor substrate may be amorphous, polycrystalline, or single-crystalline. In addition to the aforementioned types of semiconductor substrates, the semiconductor substrate employed in the present invention may also comprise a hybrid oriented (HOT) semiconductor substrate in which the HOT substrate has surface regions of different crystallographic orientation. The semiconductor substrate may be doped, undoped, or contain doped regions and undoped regions therein. The semiconductor substrate may contain regions with strain and regions without strain therein, or contain regions of tensile strain and compressive strain.

Cladding layer 104 is ideally capable of remaining single crystalline with substrate 102 to ensure sufficient carrier lifetime and mobility, as cladding layer 104 comprises a channel region of device 100. Cladding layer 104 can be formed of any well-known semiconductor material, such as silicon germanium (SiGe), indium gallium arsenide (InₓGa₁₋ₓAs_{y}), indium antimonide (InₓSb_{y}), indium gallium phosphide (InₓGa₁₋ₓP_{y}), or carbon nanotubes (CNT). In an exemplary embodiment in which substrate 102 is silicon, the semiconductor material used for cladding layer 104 is SiGe. In another embodiment. In yet another embodiment, one semiconductor body is silicon and the cladding layer is an alloy of silicon and carbon (SiC).

Cladding layer 104 is selectively formed over substrate 102 using any commonly known epitaxial processes suitable for the particular semiconductor material(s) of substrate 102. In a particular embodiment, an LPCVD process using germane and a silane as precursors forms a SiGe cladding on the silicon of substrate 102. Cladding layer 104 can be grown to have a particular composition determined by the amount of band offset desired. In a particular embodiment, a silicon germanium cladding layer having about 25 percent to about 30 percent germanium is formed. In other embodiments, the germanium concentration approaches 100 percent. Ideally, the formation process is capable of producing a single crystalline cladding from a semiconductor body seed layer of substrate 102. In an exemplary embodiment, cladding layer 104 is grown over substrate 102 to a thickness of approximately 4 nanometers (nm).

A set (i.e., one or more) of fins 106 is then formed from substrate 102, as shown in FIG. 1(b). Fin 106 may be fabricated using any suitable process including one or more photolithography and etch processes. The photolithography process may include forming a photoresist layer (not shown) overlying substrate 102 (e.g., on a silicon layer), exposing the resist to a pattern, performing post-exposure bake processes, and developing the resist to form a masking element including the resist. The masking element may then be used to etch fin 106 into the silicon layer, e.g., using reactive ion etch (RIE) and/or other suitable processes. In one embodiment, fin 106 is formed by a double-patterning lithography (DPL) process. DPL is a method of constructing a pattern on a substrate by dividing the pattern into two interleaved patterns. DPL allows enhanced feature (e.g., fin) density. Various DPL methodologies may be used including double exposure (e.g., using two mask sets), forming spacers adjacent features and removing the features to provide a pattern of spacers, resist freezing, and/or other suitable processes.

In one embodiment, fin 106 comprises silicon, while cladding layer 104 comprises SiGe. However, in another embodiment, fin 106 may comprise SiGe having a low Ge percentage, while cladding layer 104 comprises SiGe having a relatively higher percentage of Ge (or even 100% Ge concentration).

It will be appreciated that although a single fin structure is shown, some embodiments may include a plurality of fin structures configured in a closely packed manner. The fin structures may be controlled by a common gate. Such an arrangement forms, for example, multiple transistors arranged in a finger configuration to increase drive current. In other embodiments, the fin structures may be independently controlled by respective gates or a combination of common and independent gates.

As shown in FIG. 1(c), a shallow trench isolation (STI) layer 110 is then formed over substrate 102 adjacent to fin 106. Each fin 106 extends above a top surface 112 of STI layer 110. In one embodiment, STI layer 110 comprises a CVD oxide such as tetraethoxysilane (TEOS) or high-density-plasma (HDP) oxide.

Next, as shown in FIG. 1(d), another layer of SiGe is formed (e.g., epitaxially grown) along each sidewall 114 of fin 106 to extend cladding layer 104 down to top surface 112 of STI layer 110. In one embodiment, a thickness (T1) of cladding layer 104 atop fin 106 is greater than a thickness (T2) of cladding layer 104 along each sidewall 114. In yet another embodiment, T1 (e.g., 4 nm) is approximately two times (2×) greater than T1 (e.g., 2 nm). By forming cladding layer 104 with an asymmetric thickness, a SiGe charge from top of fin 106 is confined in the SiGe channel. Hole charge spill-out, which is typically present with uniform-thickness cladding, is beneficially reduced in the case that cladding layer 104 atop fin 106 is 2× thicker than cladding layer 104 along sidewalls 114. Meanwhile, this structure results in a negligible change in the 3-D stress in the channel, thus maintaining mobility performance.

Although not shown for the sake of brevity, it will be appreciated that processing of device 100 continues after the formation of cladding layer 104 along sidewalls 114. For example, subsequent processing (not shown) may include forming a set of gate stacks over fin 106, and forming source and drain regions across the gate stack. Source and drain regions may be formed by ion-implanting a source/drain region or by removing a portion of the fin and epitaxially re-growing the removed portion under doping conditions to form a source/drain region.

The gate structures may be fabricated using any suitable process including one or more photolithography and etch processes. The photolithography process may include forming a photoresist layer (not shown) overlying substrate 102 (e.g., on a silicon layer), exposing the resist to a pattern, performing post-exposure bake processes, and developing the resist to form a masking element including the resist. The masking element may then be used to etch each gate into the silicon layer, e.g., using reactive ion etch (RIE) and/or other suitable processes.

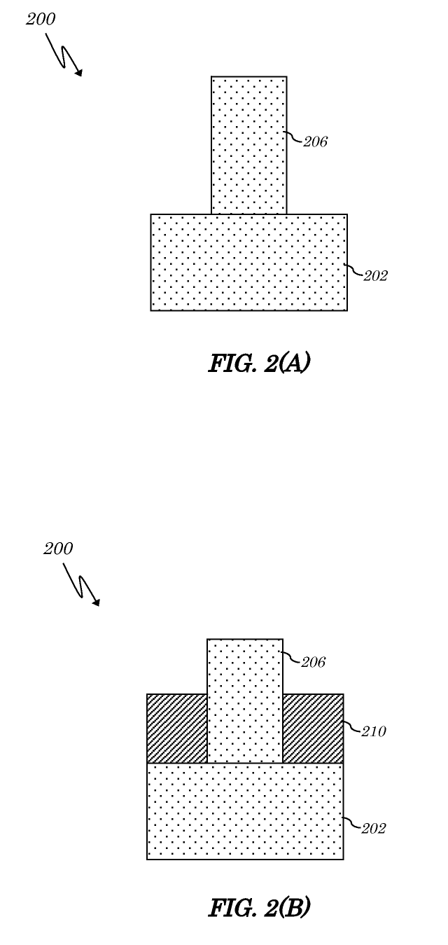

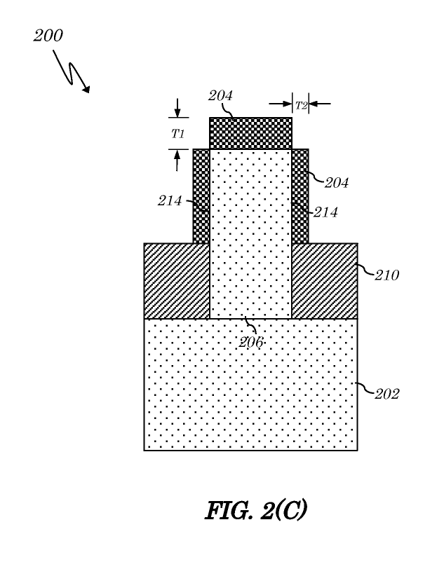

Turning now to FIG. 2(a), another embodiment for forming a FinFET device 200 is shown. In this embodiment, device 200 (e.g., a FinFET device) includes fin 206 formed from substrate 202, wherein fin 206 may be fabricated using any suitable process including one or more photolithography and etch processes. STI layer 210 is then formed over substrate 202 adjacent to fin 206, as shown in FIG. 2(b), followed by formation of cladding layer 204, as shown in FIG. 2(c). In this embodiment, cladding layer 204 is epitaxially grown atop fin 106 and along each sidewall 214 of fin 206. In order to generate a greater thickness of cladding layer 204 atop fin 206, the SiGe of cladding 204 is epitaxially grown at different rates. That is, the SiGe grown atop fin 206 is grown at a faster rate than the SiGe grown along each sidewall 214 of fin 206. As such, thickness T1 of cladding layer 204 atop fin 206 is approximately 2× greater than thickness T2 of cladding layer 204 along each sidewall 214. Again, by forming cladding layer 204 with an asymmetric thickness, a SiGe charge from top of fin 206 is confined in the SiGe channel. Hole charge spill-out, which is typically present with uniform-thickness cladding, is beneficially reduced in the case that cladding layer 204 atop fin 206 is 2× the thickness of cladding layer 204 along sidewalls 214. Meanwhile, this structure results in a negligible change in the 3-D stress in the channel, thus maintaining mobility performance.

Although not shown for the sake of brevity, it will be appreciated that processing of device 200 continues after formation of cladding layer 204 over fin 206. For example, subsequent processing (not shown) may include forming a set of gate stacks over fin 206, and forming source and drain regions across the gate stack. Source and drain regions may be formed by ion-implanting a source/drain region or by removing a portion of the fin and epitaxially re-growing the removed portion under doping conditions to form a source/drain region.

In various embodiments, design tools can be provided and configured to create the datasets used to pattern the semiconductor layers as described herein. For example, data sets can be created to generate photomasks used during lithography operations to pattern the layers for structures as described herein, including a set of fins formed from a substrate, a shallow trench isolation layer adjacent each of the set of fins, and a cladding layer formed over each of the set of fins, wherein a thickness of the cladding layer atop each of the set of fins is greater than a thickness of the cladding layer along each sidewall of the set of fins. Such design tools can include a collection of one or more modules and can also be comprised of hardware, software, or a combination thereof. Thus, for example, a tool can be a collection of one or more software modules, hardware modules, software/hardware modules, or any combination or permutation thereof.

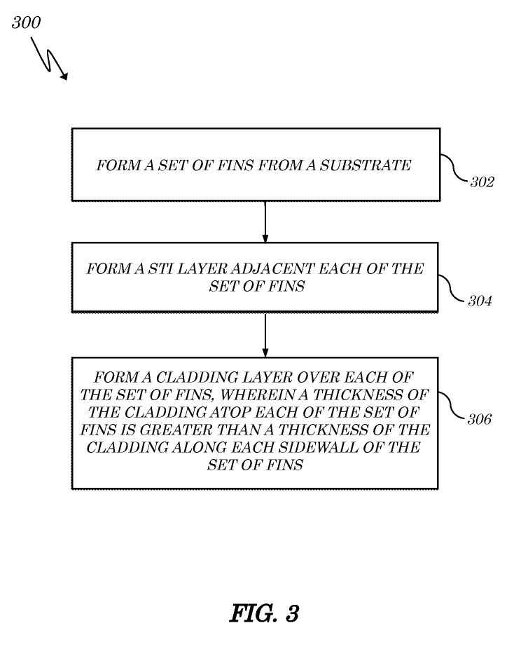

The software/hardware modules of the tool may be configured to perform a process 300, as shown in FIG. 3. Process 300 includes forming a set of fins from a substrate (302), forming a STI layer adjacent each of the set of fins (304), and forming a cladding layer over each of the set of fins, wherein a thickness of the cladding layer atop each of the set of fins is greater than a thickness of the cladding layer along each sidewall of the set of fins (306).

As another example, the tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that there has been provided approaches for providing asymmetrical channel growth of a cladding layer over fins of a FinFET device. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A fin field effect transistor (FinFET) device, comprising:
a set of fins formed from a substrate;
a shallow trench isolation layer adjacent each of the set of fins; and
a cladding layer formed over each of the set of fins, wherein a thickness of the cladding layer atop each of the set of fins is greater than a thickness of the cladding layer along each sidewall of the set of fins.

2. The FinFET device according to claim 1, wherein the cladding layer comprises silicon germanium.

3. The FinFET device according to claim 1, wherein each of the set of fins comprises silicon.

4. The FinFET device according to claim 1, wherein the thickness of the cladding layer atop the set of fins is approximately two times (2×) greater than the thickness of the cladding layer along each sidewall of the set of fins.

5. The FinFET device according to claim 1, wherein the thickness of the cladding layer atop the set of fins is approximately 4 nanometers, and wherein the thickness of the cladding layer along each sidewall of the set of fins is approximately 2 nanometers.

6. A method for forming a fin field effect transistor (FinFET) device, the method comprising:
forming a set of fins from a substrate;
forming a shallow trench isolation layer adjacent each of the set of fins; and
forming a cladding layer over each of the set of fins, wherein a thickness of the cladding layer atop each of the set of fins is greater than a thickness of the cladding layer along each sidewall of the set of fins.

7. The method according to claim 6, wherein the cladding layer comprises silicon germanium (SiGe).

8. The method according to claim 7, the forming the cladding layer comprising:
forming a layer of SiGe over the substrate;
etching the substrate and the layer of SiGe to form the set of fins; and
forming another layer of SiGe along each sidewall of the set of fins.

9. The method according to claim 8, the forming the another layer of SiGe comprising epitaxially growing the another layer of SiGe along each sidewall of the set of fins.

10. The method according to claim 7, the forming the cladding layer comprising epitaxially growing SiGe atop each of the set of fins and along each sidewall of the set of fins after formation of the STI layer.

11. The method according to claim 10, wherein the SiGe epitaxially grown atop each of the set of fins is grown at a faster rate than the SiGe grown along each sidewall of the set of fins.

12. The method according to claim 6, wherein each of the set of fins comprises silicon.

13. The method according to claim 6, wherein the thickness of the cladding layer atop the set of fins is approximately two times (2×) greater than the thickness of the cladding layer along each sidewall of the set of fins.

14. A method for providing asymmetrical channel growth of a cladding layer over fins of a fin field effect transistor (FinFET) device, the method comprising:
forming a set of fins from a substrate;
forming a shallow trench isolation layer adjacent each of the set of fins; and
forming a cladding layer formed over each of the set of fins, wherein a thickness of the cladding layer atop each of the set of fins is greater than a thickness of the cladding layer along each sidewall of the set of fins.

15. The method according to claim 14, wherein the cladding layer comprises silicon germanium (SiGe).

16. The method according to claim 15, the forming the cladding layer comprising:
forming a layer of SiGe over the substrate;
etching the substrate and the layer of SiGe to form the set of fins; and
forming another layer of SiGe along each sidewall of the set of fins.

17. The method according to claim 16, the forming the another layer of SiGe comprising epitaxially growing the another layer of SiGe along each sidewall of the set of fins.

18. The method according to claim 15, the forming the cladding layer comprising epitaxially growing SiGe atop each of the set of fins and along each sidewall of the set of fins after formation of the STI layer.

19. The method according to claim 18, wherein the SiGe epitaxially grown atop each of the set of fins is grown at a faster rate than the SiGe grown along each sidewall of the set of fins.

20. The method according to claim 14, wherein the thickness of the cladding layer atop the set of fins is approximately two times (2×) greater than the thickness of the cladding layer along each sidewall of the set of fins.
